(19) United States
(12) Patent Application Publication
(10) Pub. No.: US 2018/0240935 A1
(43) Pub. Date: Aug. 23, 2018

(54) METHOD FOR MANUFACTURING LIGHT EMITTING DEVICE

(71) Applicant: NICHIA CORPORATION, Anan-shi (JP)

(72) Inventor: Kensaku HAMADA, Komatsushima-shi (JP)

(73) Assignee: Nichia Corporation

(21) Appl. No.: 15/891,571

(22) Filed: Feb. 8, 2018

(30) Foreign Application Priority Data
Feb. 20, 2017 (JP) 2017-029062

(51) Int. Cl. H01L 33/00; H01L 33/62

(52) U.S. Cl. CPC H01L 33/0095; B23K 20/007; H01L 33/62

(57) ABSTRACT

A method for manufacturing a light emitting device includes: providing a light emitting element having a pad on a top surface thereof; forming an initial ball by melting a tip of a wire inserted through a capillary; pressing the initial ball against the pad with the capillary to deform the initial ball to form a ball part, and maintaining the capillary to stay still for a prescribed time; and applying ultrasonic waves to the capillary.

### CROSS-REFERENCE TO RELATED APPLICATIONS

This application claims priority to Japanese Patent Application No. 2017-029062 filed on Feb. 20, 2017. The entire disclosure of Japanese Patent Application No. 2017-029062 is hereby incorporated herein by reference.

### TECHNICAL FIELD

The present invention relates to a method for manufacturing a light emitting device.

### BACKGROUND ART

In the manufacturing process of a light emitting device, a step of connecting a wire for supplying power to the light emitting element is performed. A method is known by which an initial ball formed by electric discharge is rapidly cooled, and after reaching a prescribed hardness, this is pushed on the pad of the light emitting element to connect (see Japanese Laid-Open Patent Application Publication No. S60-70750, for example). As a result, it is possible to achieve good joining of the wire and the pad.

### SUMMARY

However, it is easy for the pad to be damaged by the initial ball that has been hardened.

According to an embodiment of the present invention, a method for manufacturing a light emitting device includes: providing a light emitting element having a pad on a top surface thereof; forming an initial ball by melting a tip of a wire inserted through a capillary; pressing the initial ball against the pad with the capillary to deform the initial ball to form a ball part, and maintaining the capillary to stay still for a prescribed time; and applying ultrasonic waves to the capillary.

Based on the above, it is possible to have a good junction between the wire and the pad while reducing damage to the pad.

### BRIEF DESCRIPTION OF THE DRAWINGS

FIG. 1 is a schematic cross section view showing an example of a light emitting device obtained using the method for manufacturing a light emitting device of the embodiment.

FIG. 2A is a schematic diagram for explaining the method for manufacturing the light emitting device of the embodiment.

FIG. 2B is a schematic diagram for explaining the method for manufacturing the light emitting device of the embodiment.

FIG. 2C is a schematic diagram for explaining the method for manufacturing the light emitting device of the embodiment.

FIG. 2D is a schematic diagram for explaining the method for manufacturing the light emitting device of the embodiment.

### DETAILED DESCRIPTION OF EMBODIMENTS

Hereafter, a mode for carrying out the present invention is explained while referring to the drawings. However, the mode shown hereafter is an example of a method for manufacturing the light emitting device for embodying the technical concept of the present invention, and with the present invention, the method for manufacturing a light emitting device is not limited to the following.

Also, this specification does not specify the members shown in the claims as the members of the embodiment. In particular, unless specifically noted, the gist is not to limit the claims of this disclosure to being only the constituent component dimensions, materials, shape, relative placement, etc., noted in the embodiment, and these are nothing more than explanatory examples. Moreover, the size and positional relationship, etc., of the members shown in the drawings may be exaggerated to make an explanation clear. Furthermore, in the explanation hereafter, the same name or code number indicates a member that is the same or has the same properties, and a detailed explanation will be omitted as appropriate.

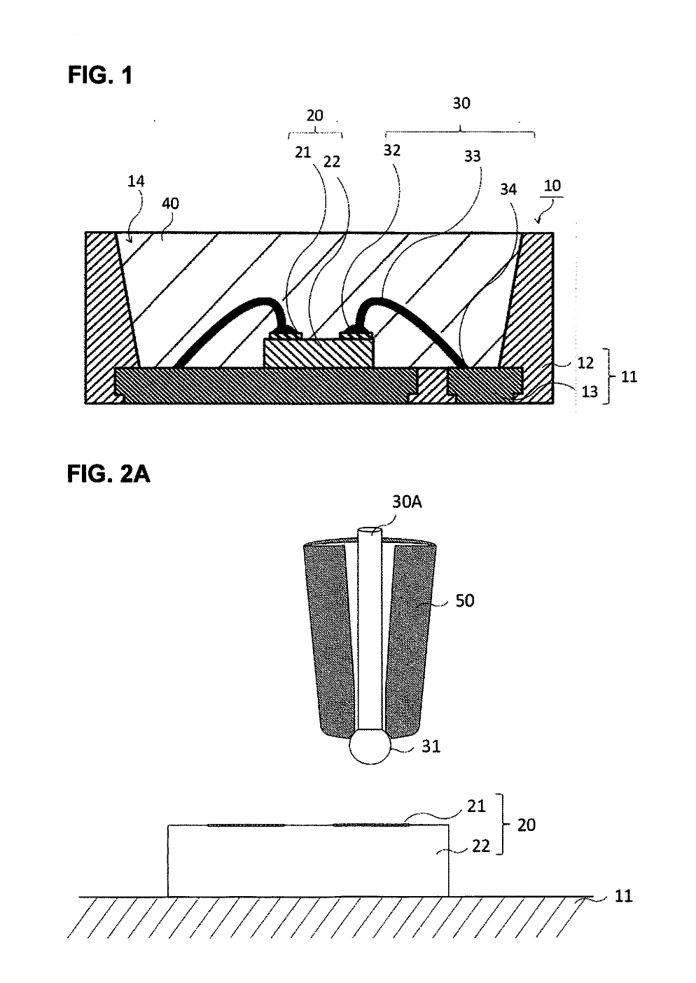

FIG. 1 shows a schematic cross section view of a light emitting device 10 obtained using the method for manufacturing the light emitting device of the embodiment. The light emitting device 10 is provided with a light emitting element 20, a substrate 11, and wires 30. It is further provided with a sealing member 40 that covers the light emitting element 20 and the wires 30.

The light emitting element 20 is provided with a laminated structure 22 that includes a semiconductor layer, and a pad 21 of the top surface of the laminated structure 22. The substrate 11 is provided with an insulating base material 12, and an electrically conductive member 13 that functions as an electrode for supplying power to the light emitting element 20.

The wires 30 are provided with a ball part 32 connected to the pad 21 of the light emitting element 20, a connection part 34 connected to the electrically conductive member 13 of the substrate 11, and a loop part 33 between the ball part 32 and the connection part 34.

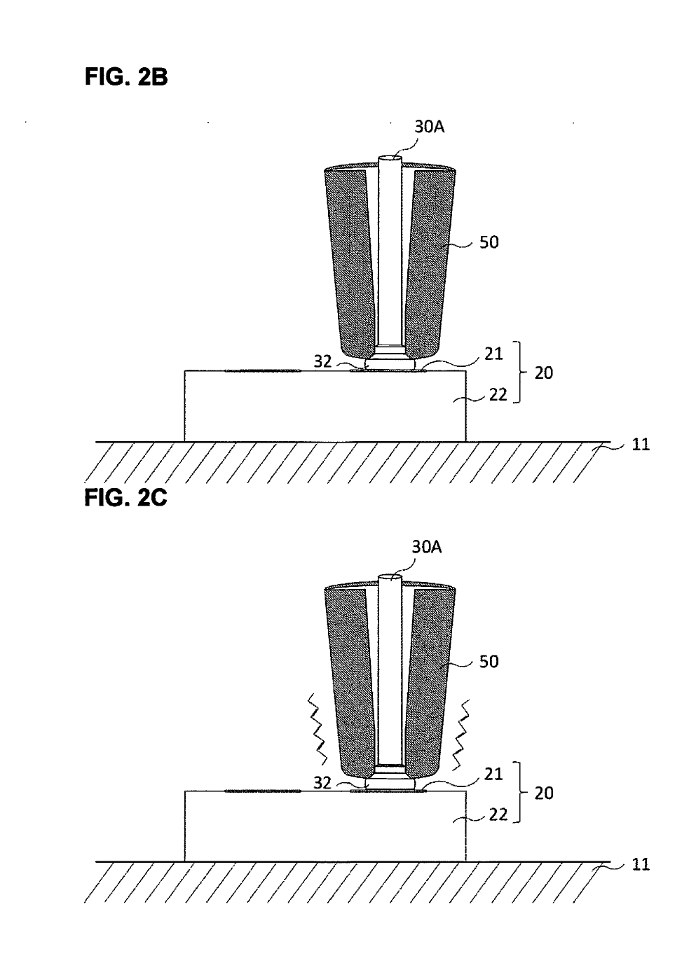

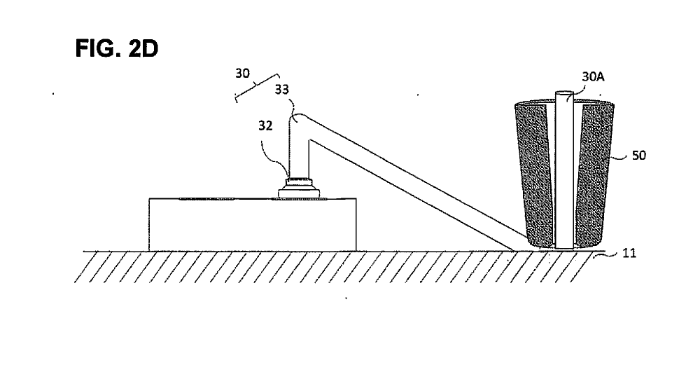

The kind of light emitting device 10 described above can be obtained using the manufacturing method noted hereafter. FIG. 2A to FIG. 2D are schematic diagrams for explaining the manufacturing method of the embodiment.

The method for manufacturing a light emitting device of the embodiment is primarily provided with the following steps. Specifically, it is provided with a step for preparing a light emitting element provided with a pad on the top surface, a step for forming an initial ball, a step for forming a ball part and having a capillary be still, and a step for applying ultrasonic waves to the capillary.

<Step for Providing a Light Emitting Element with a Pad>

As shown in FIG. 2A, the light emitting element 20 with a pad provided on the top surface is prepared. In more detail, the light emitting element 20 is provided with: a laminated structure 22 that is provided with a semiconductor layer that includes a light emitting layer, and a pad 21 that functions as an electrode for energizing the laminated structure 22.

For the laminated structure, as the semiconductor layer, for example, a nitride compound semiconductor such as InₓAl_{y}Ga_{1-x-y}N (0≤X, 0≤Y, X+Y≤1), etc. can be suitably used. As the element substrate, examples include sapphire, GaN, etc.

As shown in FIG. 2A, the light emitting element 20 can be provided with two pads 21 so as to function as a pair of electrodes on the top surface of the light emitting element 20 (top surface of the laminated structure 22). The number of pads 21 is not limited to this, and it is possible to provide 1, or 3 or more. As the pad 21, examples include Au, Pt, Pd, Rh, Ni, W, Mo, Cr, Ti, etc. The thickness of the pad 21 can be approximately 0.5 μm to 10 μm, for example.

The step of preparing the kind of light emitting element 20 described above can also be provided with a step of mounting on the substrate 11. Alternatively, the step of preparing the light emitting element 20 can also be a step for preparing the light emitting element 20 that is mounted on the substrate 11. The light emitting element 20 and the substrate 11 are fixed by an electrically conductive or an insulating joining member.

The substrate 11 is provided with an electrically conductive member 13 that functions as an electrode, and an insulating base material 12 that holds that. The substrate 11 can be provided with a recess part 14 like that shown in FIG. 1. Alternatively, the substrate 11 can be a flat plate shape. For the substrate 11, it is possible to use the substrate 11 used in the concerned field. For example, it is possible to use a resin package provided with molding resin as the base material 12, and provided with a lead as the electrically conductive member 13. Also, ceramics can be provided as the base material 12, and it is possible to use a ceramic package, etc., provided with wiring as the electrically conductive member 13.

The substrate 11 on which the light emitting element 20 is mounted is fixed at a prescribed position of a wire bonder.

<Step for Forming an Initial Ball>

To connect the wires 30 to the light emitting element 20, first, as shown in FIG. 2A, an initial ball 31 is formed. In more detail, by melting the tip of a wire 30A inserted through the inside of the through hole of a capillary 50 using electric discharge, etc., the initial ball 31 is formed. The initial ball 31 indicates a spherical part provided on the tip of the wire 30A. The conditions for electric discharge, etc., can be selected as appropriate according to the material, composition, or diameter of the wire 30A, or the target size, etc., of the initial ball 31.

<Step for Abutting the Initial Ball on the Pad and Deforming>

Next, as shown in FIG. 2B, the initial ball 31 abuts the pad 21 of the top surface of the light emitting element 20, and is pressed by the capillary 50. As a result, the spherical initial ball 31 is deformed and becomes a semispherical ball part 32. Then, in a state with the capillary 50 in contact with the ball part 32, the capillary 50 is kept still for a prescribed time. In more detail, the capillary 50 applies a load until the ball part 32 reaches a prescribed thickness, and this is kept still in a state with the load applied so as not to deform further while maintaining that height.

The prescribed time for which the capillary 50 is kept still can be 0.1 msec to 255 msec, for example, and 2 msec to 100 msec is preferable. By providing this still time, the ball part 32 gradually increases in hardness. In more detail, the temperature is raised using electric discharge for melting, and the ball part 32 for which the hardness has decreased cools with the passing of time, and the hardness increases. The cooling method can be a method of natural cooling, in which the capillary 50 simply has operation stopped and is kept still, or a method such as forced cooling by blowing inert gas such as freon gas, etc., as a coolant while kept still.

<Step for Applying Ultrasonic Waves to the Capillary>

As described above, after the capillary 50 is kept still for a prescribed time, ultrasonic waves are applied as shown in FIG. 2C. The ultrasonic waves can be a frequency of approximately 60 kHz to 150 kHz, for example, and the application time can be 1 msec to 255 msec, but is preferably approximately 5 msec to 100 msec. Because the ball part 32 is kept still for a prescribed time as described above, it is harder than the hardness directly after being abutted on the pad 21. By causing vibration by applying ultrasonic waves on the ball part 32 in this way, it is possible to make it easier to have a part of the ball part 32 sink into the interior of the pad.

It is also possible to reduce the damage when abutting the initial ball 31 on the pad 21 by keeping still after abutting the initial ball 31 on the pad 21 and forming the ball part 32, rather than keep still in a state with the initial ball 31 formed on the tip of the capillary 50.

By applying ultrasonic waves, the oxide film or contamination, etc., of the interface of the pad 21 and the ball part 32 is removed by ultrasonic vibration. As described above, by making the ball part 32 be harder than the initial ball 32, the ultrasonic vibration is transmitted more easily, and it is easier for bonds between crystal particles to occur at the junction interface. As a result, it is possible to have a good junction between the ball part 32 and the pad 21.

As described above, after joining the ball part 32 to the pad 21, as shown in FIG. 2D, the capillary 50 is moved, the wire 30A is abutted on the substrate 11, and ultrasonic waves and a load are applied. After that, by cutting the wire 30A, it is possible to have the junction part 34 of the wire 30 like that shown in FIG. 1.

Examples of the wire 30 include electrically conductive wire that uses metals such as gold, silver, copper, platinum, aluminum, etc., and alloys that contain at least those metals. In particular, silver-containing wire has lower light absorbance and higher reflectivity than gold wire, so it is useful to use this as the wire used for the light emitting device. However, silver-containing wire is harder than gold wire, and is susceptible to having poorer joining properties. By joining the silver-containing wire using the kind of joining method described above, it is possible to have good joining properties with the pad 21. As the silver-containing wire, it is possible to use a wire with silver content of 10% to 100%. The silver-containing wire can also contain a metal other than silver, such as gold, palladium, etc.

The diameter of the wire 30 is preferably 18 μm to 30 μm. The linear expansion coefficient of the wire is preferably 14.2×10⁻⁶-19.7×10⁻⁶, and more preferably 17.6×10⁻⁶-18.9×10⁻⁶.

### <Other Steps>

As another step, it is also possible to provide a step of forming the sealing member 40 for sealing the light emitting element 20 and the wire 30. As the material of the sealing member, a translucent item through which light from the light emitting element can be transmitted, and that is light resistant, is preferable. Specific examples of materials include translucent, insulating resin compositions through which light from the light emitting element can be transmitted, such as a silicone resin composition, a modified silicone resin composition, an epoxy resin composition, a modified epoxy resin composition, an acrylic resin composition, etc. It is also possible to use silicone resin, epoxy resin, urea resin, fluororesin, and hybrid resins, etc., that include at least one or more of these. Furthermore, this is not limited to these organic substances, and it is also possible to use inorganic substances such as glass, silica sol, etc. Added to this kind of material, it is also possible to contain a coloring agent, a light diffusing agent, a light reflective material, various fillers, a wavelength conversion member (phosphor), etc., as desired.

Examples of the phosphor include oxide type, sulfide type, and nitride type phosphors, etc. For example, when using a gallium nitride type light emitting element that emits blue light as the light emitting element, it is possible to use at least one, or two or more items among YAG type and LAG type that absorb blue light and emit yellow to green light, SiAlON type (β sialon) that emits green light, SCASN, CASN type, and KSF type phosphor (K₂SiF₆:Mn) that emits red light, sulfide type phosphor, nano phosphor, etc. These phosphors are preferably contained in the sealing member at 5 mass %-120 mass %.

### WORKING EXAMPLE

Following is a detailed explanation of a working example of the present disclosure.

### Working Example 1

A resin package provided with a recess part for which the opening shape is circular is prepared as the substrate. For the substrate, molding resin is formed integrally on a lead frame that has copper as a major component, and it is possible to form a plurality of light emitting devices on one substrate. The light emitting element is mounted via the joining member that has resin as a major component on the lead frame which is exposed at the bottom surface of the recess part. The light emitting element is provided with a laminated structure that is provided with a gallium nitride semiconductor layer, and a pad that has gold as a major component on the top surface. The pad is circular in the top view, and two pads, a p side pad and an n side pad, are provided. The pad thickness is 1.2 μm.

The substrate described above is fixed at a prescribed position of the wire bonder. The capillary is placed above the substrate. The wire is inserted through the inside of the through hole of the capillary. The wire mainly contains Ag 80% and Au 20%. The diameter of the wire is 25 μm. On the wire extending from the tip of the capillary, current of 30 mA is applied to do electric discharge, and the initial ball of diameter 49 gm is formed. After that, the initial ball is abutted on the pad, a load of 30 to 45 gf is applied on the capillary and pressed, and a 9 μm thick ball part is formed. In that state, this is kept still for approximately 6 milliseconds. Next, ultrasonic waves of frequency 60 KHz are applied for 10 msec. Next, the capillary is moved, and the wire is joined on the lead frame inside the recess part.

A liquid state resin member is injected into the recess part and hardened. The resin member contains as the major components a silicone type resin and a YAG phosphor. Finally, the substrate is diced to make the light emitting devices.

The joining strength of the wire joined to the pad as described above was measured using a shear strength test. A comparison was done with the joining strength of the wire joined using a method for which time kept still is not provided for the capillary, with ultrasonic waves applied immediately after the ball part is formed. The wire joined using the joining method of this working example had approximately a 20 to 30% improvement in shear strength compared to the wire of the comparison example. Also, the residual amount of gold on the pad after shearing increased 14 to 15%.

The light emitting device of the present disclosure can be used for illumination equipment, displays, the backlight for the liquid crystal display device of a cell phone, a video illumination auxiliary light source, or other general consumer use light source, etc.

What is claimed is:

1. A method for manufacturing a light emitting device comprising:
providing a light emitting element having a pad on a top surface thereof;
forming an initial ball by melting a tip of a wire inserted through a capillary;
pressing the initial ball against the pad with the capillary to deform the initial ball to form a ball part, and maintaining the capillary to stay still for a prescribed time; and
applying ultrasonic waves to the capillary.

2. The method for manufacturing a light emitting device according to claim 1, wherein
the prescribed time is 0.1 msec to 255 msec.

3. The method for manufacturing a light emitting device according to claim 1 or claim 2, wherein
the wire contains 10% to 100% silver.
